(19) United States
(12) Patent Application Publication
(10) Pub. No.: US 2008/0164794 A1
(43) Pub. Date: Jul. 10, 2008

(54) MODULAR SERVER CABINET

(75) Inventors: HSIU-CHANG LAI, Tu-Cheng (TW); KE SUN, Shenzhen (CN); ZHEN-XING YE, Shenzhen (CN)

Correspondence Address: PCE INDUSTRY, INC.;ATT. CHENG-JU CHIANG, 458 E. LAMBERT ROAD, FULLERTON, CA, 92835, US

(73) Assignees: HONG FU JIN PRECISION INDUSTRY (ShenZhen) CO., LTD., Shenzhen City (CN); HON HAI PRECISION INDUSTRY CO., LTD., Tu-Cheng (TW)

(21) Appl. No.: 11/861,303

(22) Filed: Sep. 26, 2007

(30) Foreign Application Priority Data
Jan. 8, 2007 (CN) 200710200021.8

(51) Int. Cl. H05K 5/02

(52) U.S. Cl. 312/298

(57) ABSTRACT

A modular server cabinet includes a first cabinet unit and a second cabinet unit. The first and second cabinet units respectively have a first receiving space and a second receiving space, for accommodating a plurality of servers therein. The second cabinet unit is capable of being combined with the first cabinet unit in a variety of side-by-side arrangements to adapt to a user's available space. The second receiving space communicates with the first receiving space of the first cabinet unit to promote air circulation and heat dissipation in the modular server cabinet.

### BACKGROUND

1. Field of the Invention

The present invention relates to server cabinets, and more particularly to a modular server cabinet.

2. Description of Related Art

Usually, a server cabinet includes a rack for accommodating a plurality of servers therein, and a plurality of removable panels attached to corresponding sides of the rack.

Generally, server cabinets come in standard sizes, and thus, are not easily modified according to need.

What is desired, therefore, is a modular server cabinet which has a plurality of cabinet units, which can be combined together in a variety of side-by-side arrangements.

### SUMMARY

An exemplary modular server cabinet includes a first cabinet unit having a first receiving space for accommodating a plurality of servers therein, and a second cabinet unit having a second receiving space for accommodating a plurality of another servers therein. The second cabinet unit is capable of being combined with the first cabinet unit in a variety of side-by-side arrangements.

Other advantages and novel features of the present invention will become more apparent from the following detailed description of preferred embodiment when taken in conjunction with the accompanying drawings, in which:

### BRIEF DESCRIPTION OF THE DRAWINGS

FIG. 1 is an isometric view of a modular server cabinet in accordance with a first embodiment of the present invention, the modular server cabinet including two cabinet units vertically stacked together, with a top plate of the lower cabinet unit and a base plate of the upper cabinet unit removed;

FIG. 2 is an exploded, isometric view of one cabinet unit of FIG. 1, the cabinet unit including a rack;

FIG. 3 is an enlarged view of the rack of FIG. 2;

FIG. 4 is an assembled view of FIG. 2;

FIG. 5 is an enlarged view of a circled portion V of FIG. 1;

FIG. 6 is an isometric view of a modular server cabinet in accordance with a second embodiment of the present invention, the modular server cabinet including two cabinet units of FIG. 4, combined together in a left and right arrangement, with a right side plate of the left cabinet unit and a left side plate of the right cabinet unit removed;

FIG. 7 is an isometric view of a modular server cabinet in accordance with a third embodiment of the present invention, the modular server cabinet including two cabinet units of FIG. 4, combined together in a back-to-back arrangement, with two back plates of the front and back cabinet units removed; and

FIG. 8 is an isometric view of a modular server cabinet in accordance with a fourth embodiment of the present invention, the modular server cabinet including four cabinet units of FIG. 4, combined together in a two-by-two vertical arrangement, and corresponding plates at junctions of the four cabinet units removed.

### DETAILED DESCRIPTION

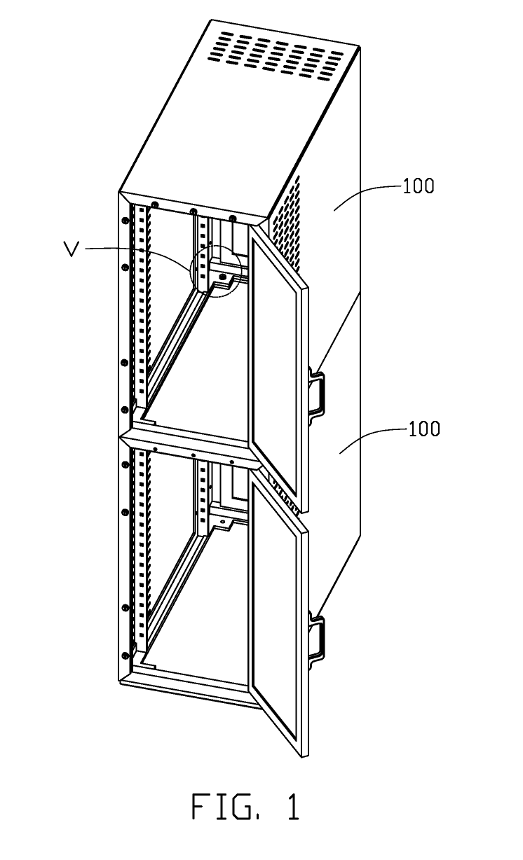

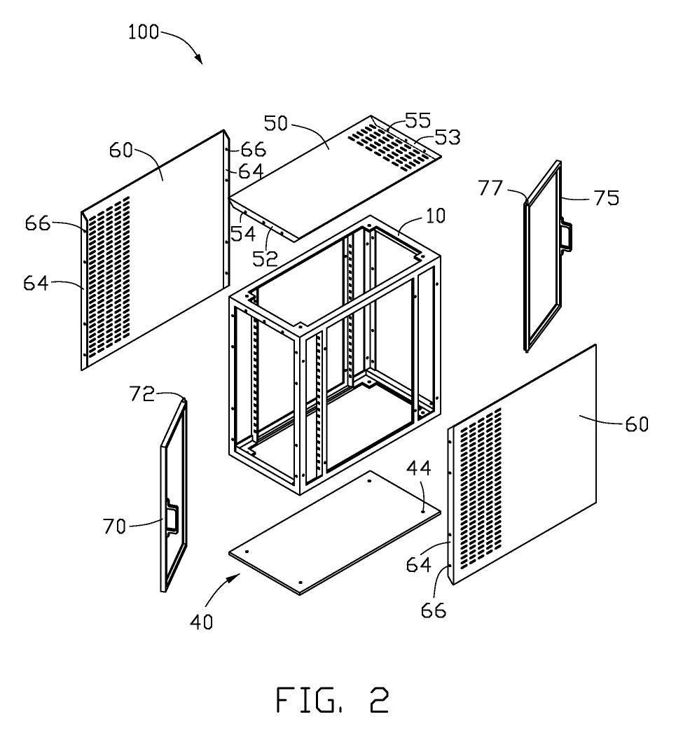

Referring to FIGS. 1 and 2, in a first embodiment of the present invention, the modular server cabinet includes two cabinet units 100 vertically stacked together. Each cabinet unit 100 includes a rack 10, a base plate 40, a top plate 50, two side plates 60, a front plate 70, and a back plate 75.

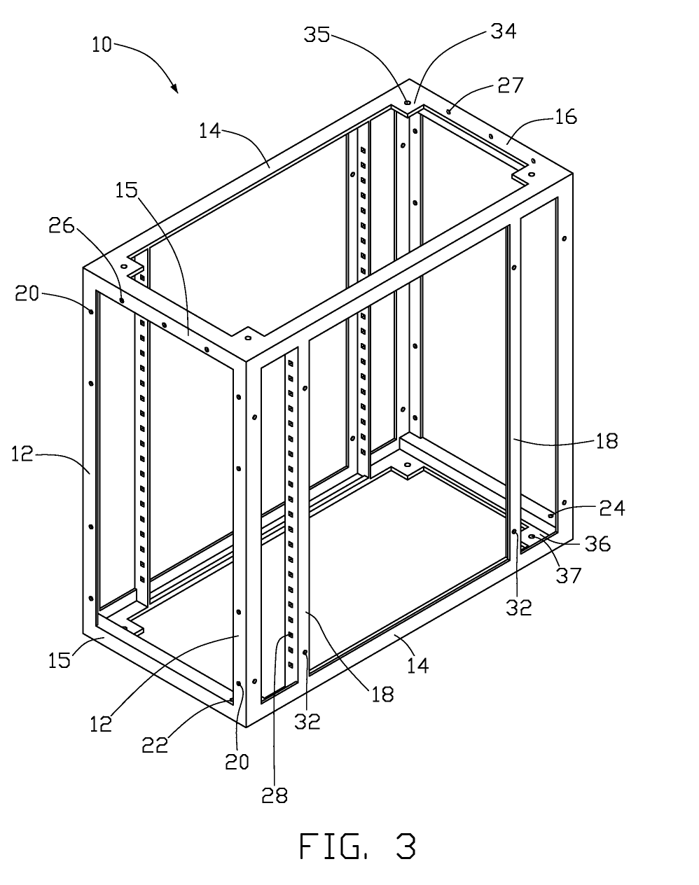

Referring also to FIG. 3, the rack 10 includes four vertical supporting members 12 respectively arranged at four corners thereof, four side girders 14 arranged at two opposite lateral sides thereof, two front girders 15 arranged at a front thereof, and two back girders 16 arranged at a back thereof, together defining a receiving space to accommodate a plurality of servers therein. The two upper side girders 14 and the upper front and back girders 15, 16 are located in the same horizontal plane and respectively connected between tops of every two adjacent supporting members 12. The two lower side girders 14 and the lower front and back girders 15, 16 are located in the same horizontal plane, parallel to the aforementioned plane, and respectively connected between bottoms of every two adjacent supporting members 12. Each of the supporting members 12 and the side girders 14 is L-shaped in cross-section. Each of the front and back girders 15, 16 is rectangular in cross-section. A plurality of coupling holes 20, such as threaded holes, is defined in each supporting member 12. Two aligned pivoting holes 22 are respectively defined in the two front girders 15. Two aligned pivoting holes 24 are respectively defined in the two back girders 16. A plurality of coupling holes 26, 27, such as threaded holes, is respectively defined in the upper front and back girders 15, 16. A tab 34 extends in from each of intersections of the two upper side girders 14 and the upper front and back girders 15, 16. A coupling hole 35, such as a threaded hole, is defined in each tab 34. A tab 36 extends in from each of intersections of the two lower side girders 14 and the lower front and back girders 15, 16. A coupling hole 37, such as a threaded hole, is defined in each tab 36.

Two installing members 18 are vertically connected between the two side girders 14 at each lateral side of the rack 10. Each installing member 18 has a right-angled cross-section, and is near to a corresponding supporting member 12. A plurality of linearly arranged installing holes 28 is defined in a side of each installing member 18, facing a corresponding supporting member 12.

Referring again to FIG. 2, the base plate 40 is rectangular, with a plurality of stands (not visible) attached to a bottom surface thereof. Four fixing holes 44 are respectively defined in four corners of the base plate 40, corresponding to the coupling holes 37 of the bottom of the rack 10.

The top plate 50 includes two mounting flanges 52, 53 perpendicularly bent from a front side and a back side thereof in the same direction, respectively. A plurality of through holes 54, 55 is respectively defined in the two mounting flanges 52, 53, respectively corresponding to the coupling holes 26, 27 of the upper front and back girders 15, 16.

Each side plate 60 includes two mounting flanges 64 perpendicularly bent from a front side and a back side thereof in the same direction, respectively. A plurality of through holes 66 is defined in each mounting flange 64, corresponding to the coupling holes 20 of a corresponding supporting member 12.

The front plate 70 includes two pivoting pins 72 respectively protruding from a top and a bottom thereof, corresponding to the two pivoting holes 22 of the front girders 15.

The back plate 75 includes two pivoting pins 77 respectively protruding from a top and a bottom thereof, corresponding to the two pivoting holes 24 of the back girders 16.

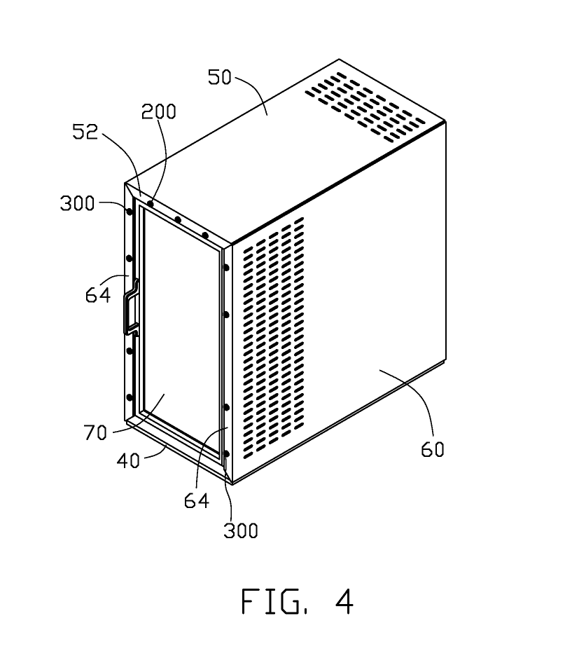

Referring also to FIG. 4, in assembling the cabinet unit, the base plate 40 is mounted to the bottom of the rack 10 via fixing members (not shown) being inserted through the fixing holes 44 of the base plate 40 and engaged in the corresponding coupling holes 37 of the bottom of the rack 10. The stands of the base plate 40 are for supporting the rack 10. The top plate 50 is mounted to the top of the rack 10 via fasteners, such as screws 200, being inserted through the through holes 54, 55 of the top plate 50 and engaged in the corresponding coupling holes 26, 27 of the upper front and back girders 15, 16. The two side plates 60 are respectively mounted to the two lateral sides of the rack 10 via fasteners, such as screws 300, being inserted through the through holes 66 of the side plates 60 and engaged in the coupling holes 20 of the corresponding supporting members 12. The front plate 70 is mounted to the front of the rack 10 via the pivoting pins 72 of the front plate 70 being respectively pivotably engaged in the corresponding pivoting holes 22 of the two front girders 15. The back plate 75 is mounted to the back of the rack 10 via the pivoting pins 77 of the back plate 75 being respectively pivotably engaged in the corresponding pivoting holes 24 of the two back girders 16. A plurality of supporting plates (not shown) is mounted among the installing members 18 via a plurality of connecting members respectively passing through the corresponding installing holes 28 of the installing members 18 and engaged with the corresponding supporting plates. A plurality of servers received in the rack 10 is respectively supported on the supporting plates.

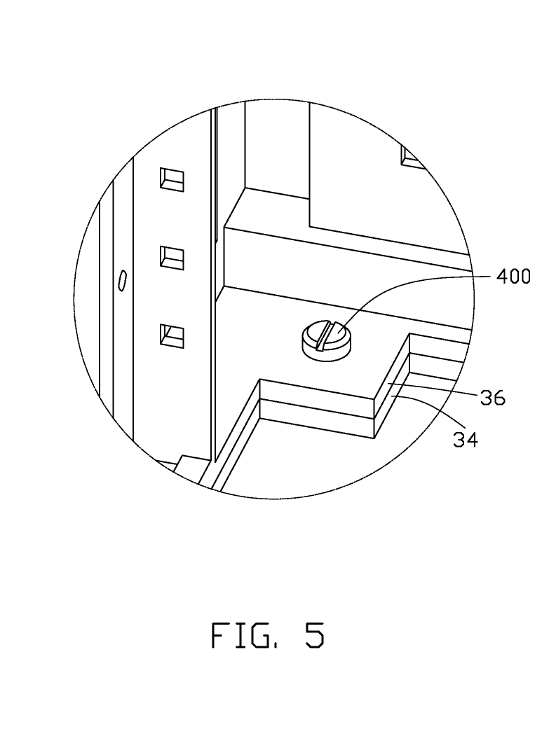

Referring again to FIG. 1, when two upper and lower cabinet units 100 need to be assembled together, the top plate 50 is removed from the lower cabinet unit 100, and the base plate 40 is removed from the upper cabinet unit 100. The upper cabinet unit 100 is placed atop the lower cabinet unit 100, with the coupling holes 37 of the upper cabinet unit 100 aligning with the corresponding coupling holes 35 of the lower cabinet unit 100. Four coupling members, such as screws 400, are respectively engaged in the coupling holes 37, of the upper and lower cabinet units 100, as shown in FIG. 5. Thus, a modular server cabinet is conveniently formed to suit a user's need for more space, and configured to be accommodated in a high but narrow space.

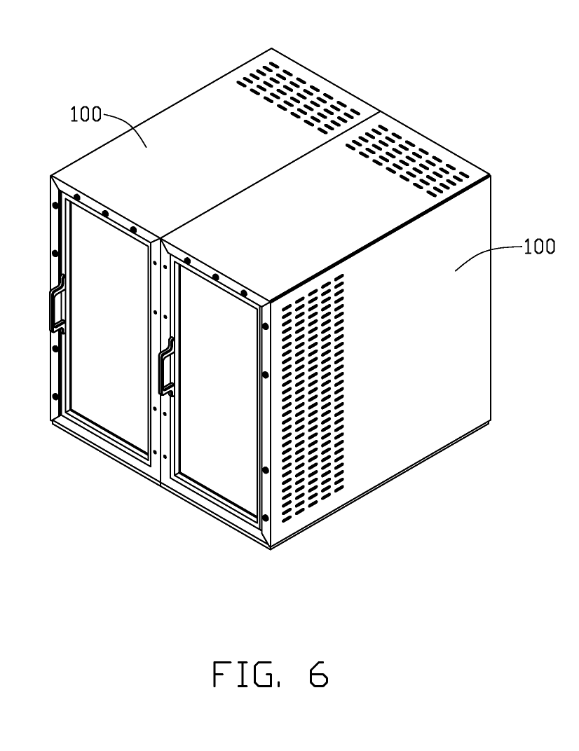

Referring also to FIG. 6, in a second embodiment of the present invention, a plurality of coupling holes 32 (as shown in FIG. 3), such as threaded holes, is defined in the other side of each installing member 18, facing the outer side of the rack 10. When a user's room space is wide but is low, two left and right cabinet units 100 are combined together. The right side plate 60 of the left cabinet unit 100 and the left side plate 60 of the right cabinet unit 100 are removed. The left and right cabinet units 100 are placed together, with the coupling holes 32 at the right lateral side of the left cabinet unit 100 aligning with the coupling holes 32 at the left lateral side of the right cabinet unit 100. A plurality of coupling members (not visible) is respectively engaged in the coupling holes 32 of the left cabinet unit 100 and the corresponding coupling holes 32 of the right cabinet unit 100.

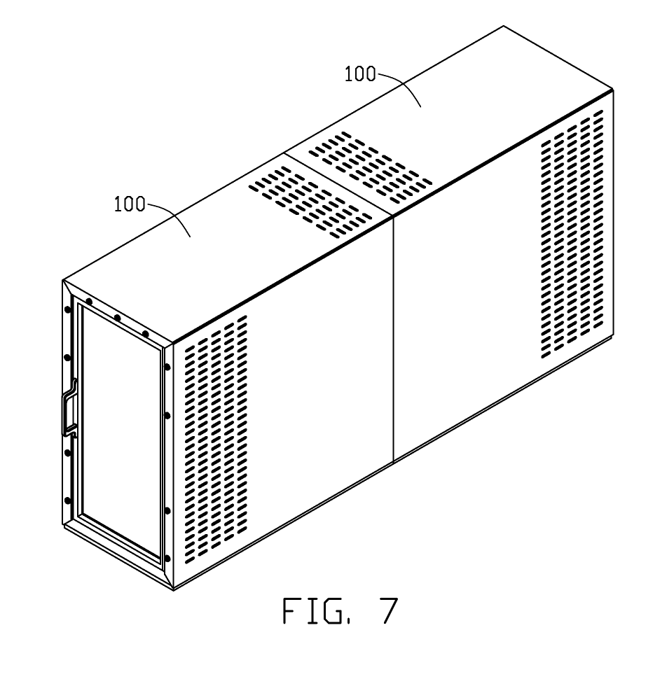

Referring also to FIG. 7, in a third embodiment of the present invention, the back plates 75 of two of the above-mentioned cabinet unit 100 are removed. The two cabinet units 100 are placed in a back-to-back arrangement, with the coupling holes 20, 27 at the back of the front cabinet unit 100 aligning with the coupling holes 20, 27 at the back of the back cabinet unit 100, respectively. A plurality of coupling members (not visible) is respectively engaged in the coupling holes 20, 27 of the front cabinet unit 100 and the corresponding coupling holes 20, 27 of the back cabinet unit 100. Thus, a modular server cabinet is formed suitable for a long narrow space having access at both ends.

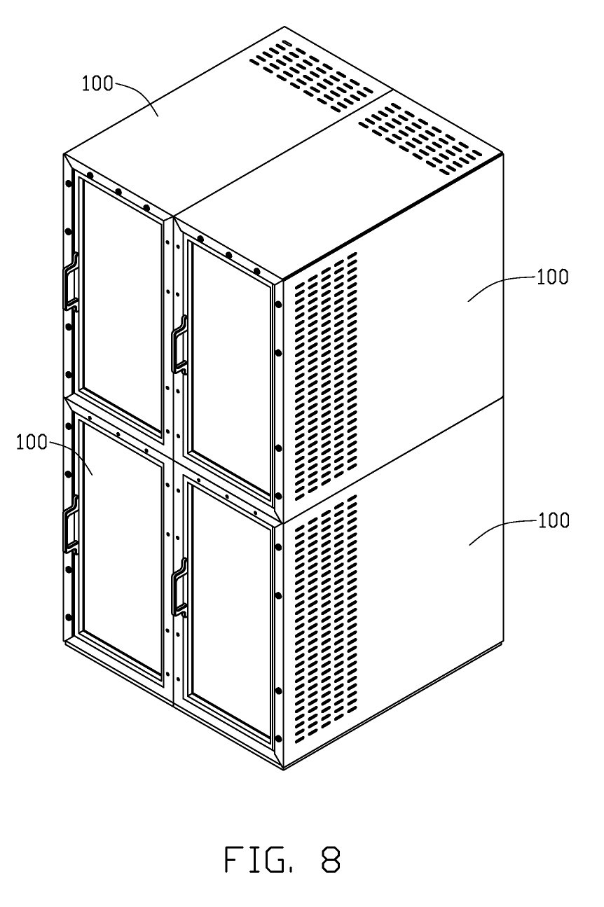

Referring also to FIG. 8, in a fourth embodiment of the present invention, when a larger capacity server cabinet is needed, four of the above-mentioned cabinet units 100 are combined together in a two-by-two vertical arrangement.

In the above-mentioned various embodiments, the cabinet units 100 are combined together in a variety of side-by-side arrangements. The abutting plates of the cabinet units 100 are removed to communicate the corresponding receiving spaces to promote air circulation and heat dissipation in the modular server cabinet.

It is to be understood, however, that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A modular server cabinet comprising:
a first cabinet unit having a first receiving space configured for accommodating a plurality of servers therein; and
a second cabinet unit having a second receiving space configured for accommodating a plurality of another servers therein, the second cabinet unit capable of being combined with the first cabinet unit in a variety of side-by-side arrangements.

2. The modular server cabinet as described in claim 1, wherein the first and second receiving spaces of the first and second cabinet units communicate with each other.

3. The modular server cabinet as described in claim 2, wherein each of the first and second cabinet units comprises a rack, the rack comprises four supporting members respectively arranged at four corners thereof, four side girders arranged at two opposite lateral sides thereof, two front girders arranged at a front thereof, and two back girders arranged at a back thereof, together defining the first or second receiving space.

4. The modular server cabinet as described in claim 3, wherein two of the side girders, one of the front girders, and one of the back girders are respectively connected between tops of every two adjacent supporting members, and the remaining side, front, and back girders are respectively connected between bottoms of every two adjacent supporting members.

5. The modular server cabinet as described in claim 4, wherein each of the supporting members and the side girders is L-shaped in cross-section.

6. The modular server cabinet as described in claim 4, wherein each of the front and back girders is rectangular in cross-section.

7. The modular server cabinet as described in claim 5, wherein a plurality of coupling holes is defined in each of the supporting members and the front and back girders configured for combining the first cabinet unit to a desired side of the second cabinet unit via coupling members.

8. The modular server cabinet as described in claim 5, wherein a tab defining a coupling hole extends in from each of intersections of the side girders and the front and back girders of the rack, to combine the first cabinet unit to one of top and bottom of the second cabinet unit via coupling members.

9. The modular server cabinet as described in claim 5, wherein two installing members are connected between the two side girders at each of the two lateral sides of the rack, and a plurality of coupling holes is defined in each of the installing members configured for combining the first cabinet unit to one of the lateral sides of the second cabinet unit via coupling members.

10. The modular server cabinet as described in claim 9, wherein each of the installing members has a right-angled cross-section, a plurality of installing holes is defined in a side of each of the installing members, facing a corresponding supporting member, the coupling holes are defined in the other side thereof, facing an outer side of the rack, and the installing members are configured for supporting a plurality of servers via the installing holes thereof.

11. A server cabinet comprising:
a rack with six sides comprising four supporting members respectively arranged at four corners thereof, four side girders arranged at two opposite lateral sides thereof, two front girders arranged at a front side thereof, and two back girders arranged at a back side thereof, together defining a receiving space configured for accommodating a plurality of servers therein, a plurality of first combining structures and a plurality of second combining structures being respectively formed at one of the sides and another one of the sides of the rack configured for selectively combining with another rack.

12. The server cabinet as described in claim 11, wherein two of the side girders, one of the front girders, and one of the back girders are respectively connected between tops of every two adjacent supporting members, and the remaining side, front, and back girders are respectively connected between bottoms of every two adjacent supporting members, together defining the rack to be rectangular.

13. The server cabinet as described in claim 12, wherein the first combining structures comprise a plurality of coupling holes defined in the one of the sides of the rack, and the second combining structures comprise a plurality of coupling holes defined in the another one of the sides of the rack.

14. The server cabinet as described in claim 12, wherein each of the supporting members and the side girders is L-shaped in cross-section.

15. The server cabinet as described in claim 12, wherein each of the front and back girders is rectangular in cross-section.

16. The server cabinet as described in claim 12, further comprising a plurality of plates mounted to exterior sides of the rack to enclose the receiving space.

17. A server cabinet comprising:
a pair of racks with the same structures, each of the racks having a receiving space configured for accommodating a plurality of servers therein, one of the racks being detachably attached to the other one of the racks in a side-by-side arrangement; and
a plurality of plates attached to the racks to enclose the receiving spaces.

18. The server cabinet as described in claim 17, wherein each of the racks comprises eight girders connected together to form a hexahedron configuration, a plurality of coupling holes is defined in the girders such that the racks are assembled together via coupling members respectively engaging in the coupling holes.
